(19) United States
(12) Patent Application Publication
(10) Pub. No.: US 2020/0410710 A1
(43) Pub. Date: Dec. 31, 2020

(54) METHOD FOR MEASURING ANTENNA DOWNTILT BASED ON LINEAR REGRESSION FITTING

(71) Applicant: Wuyi University, Jiangmen (CN)

(72) Inventors: Wenbo DENG, Jiangmen (CN); Yikui ZHAI, Jiangmen (CN); Qirui KE, Jiangmen (CN); Yueting WU, Jiangmen (CN); Junying GAN, Jiangmen (CN); Ying XU, Jiangmen (CN); Tianlei WANG, Jiangmen (CN); Xi WU, Jiangmen (CN); Liyan CHEN, Jiangmen (CN)

(21) Appl. No.: 16/975,599

(22) PCT Filed: Mar. 1, 2019
(86) PCT No.: PCT/CN2019/076720

§ 371 Date: Aug. 25, 2020

(30) Foreign Application Priority Data
Nov. 15, 2018 (CN) 201811363450.1

(51) Int. Cl. G06T 7/73; G01C 1/00; G01R 29/10; G06T 7/11; G06T 7/13; G06T 7/136

(52) U.S. Cl. CPC G06T 7/73; G01C 1/00; G01R 29/10; G06T 2207/20084; G06T 7/13; G06T 7/136; G06T 2207/20081; G06T 7/11

(57) ABSTRACT

The present disclosure discloses a method for measuring an antenna downtilt based on linear regression fitting, including: performing image instance segmentation on an inputted original antenna image using a deep learning method to obtain a segmented image; performing mask processing on the segmented image; performing mathematically linear modeling and fitting on the segmented image subjected to mask processing; and the performing mathematically linear modeling and fitting on the segmented image subjected to mask processing including: extracting pixel value coordinates of an antenna edge contour from the segmented image subjected to mask processing, and capturing a pixel value of a right-end edge of the antenna; and fitting the pixel value coordinates into a straight line by using a mathematically linear modeling and fitting method to obtain an angle of the antenna downtilt.

### CROSS REFERENCE TO RELATED APPLICATIONS

This application is a national stage application under 35 U.S.C. 371 of PCT Application No. PCT/CN2019/076720, filed on 1 Mar. 2019, which PCT application claimed the benefit of Chinese Patent Application No. 2018113634501, filed on 15 Nov. 2018, the entire disclosure of each of which are hereby incorporated herein by reference.

### TECHNICAL FIELD

The present disclosure relates to the field of communication measurement, and more particularly, to a method for measuring an antenna downtilt based on linear regression fitting.

### BACKGROUND

In the field of communications, an antenna downtilt needs to be adjusted frequently. As one of the important parameters determining a coverage area of signals of base stations, the antenna downtilt needs to be accurately designed in the initial stage of network planning. Furthermore, after the base stations are put into operation, with the development of services and changes of users and surrounding signal environments, it is also required to accurately adjust the downtilt.

At present, a slope meter is generally used to measure a mechanical downtilt of an antenna of a base station. When measuring the mechanical downtilt of the antenna using the slope meter, a measurer need to climb up an iron tower or hold a pole to get close to the antenna to measure, which is not only dangerous and troublesome, but also affects the accuracy of the measurement. With the development of technologies, a GSM-R system has emerged. The system is a measurement tool allowing the measurer to accurately measure the antenna downtilt without getting close to the antenna, the measurement of the antenna downtilt of the base station could be carried out without climbing up a tower, test points of the base station could be networked to monitor the downtilt of the base station in real-time. However, installation of sensors is time-consuming and is high in cost. Moreover, there exist differences between new towers and old towers, the number of towers of base stations and the number of the base stations, etc. Therefore, this method is of low practicability, long operational cycle, and difficult to be implemented. Therefore, it is necessary to design an angle measurement method which is simple in operation and reliable in performance.

### SUMMARY

To solve the above problems, an objective of embodiments of the present disclosure is to provide a method for measuring an antenna downtilt based on linear regression fitting, so as to safely, efficiently, quickly and accurately measure an antenna downtilt.

In order to solve the above problems, the embodiments of the present disclosure adopt following technical solution.

A method for measuring an antenna downtilt based on linear regression fitting includes: performing image instance segmentation on an inputted original antenna image using a deep learning method to obtain a segmented image; performing mask processing on the segmented image; performing mathematically linear modeling and fitting on the segmented image subjected to mask processing; and the performing mathematically linear modeling and fitting on the segmented image subjected to mask processing includes: extracting pixel value coordinates of an antenna edge contour from the segmented image subjected to mask processing, and capturing a pixel value of a right-end edge on an antenna plane located in a front side; and fitting the pixel value coordinates into a straight line by using a mathematically linear modeling and fitting method and obtaining a slope of the straight line to obtain an angle of the antenna downtilt.

Further, the performing image instance segmentation on an inputted antenna image using a deep learning method to obtain a segmented image includes: obtaining an antenna candidate box and an antenna characteristic diagram by using a convolutional neural network; and generating a region of interest from the antenna candidate box and obtaining a characteristic diagram of the region of interest with reference to the antenna characteristic diagram to perform pixel correction on the region of interest.

Further, the performing image instance segmentation on an inputted antenna image using a deep learning method to obtain a segmented image further includes: predicting the region of interest, to obtain a regression bounding box mapped from the antenna characteristic diagram, and predicting a class of a pixel in the region of interest to obtain the segmented image.

Further, the pixel correction is performing alignment processing by using a residual network; and the pixel correction includes two quantization processes, which are mapping from the region of interest to the antenna characteristic diagram and mapping from the antenna characteristic diagram to the original antenna image respectively.

Further, the performing mask processing on the segmented image includes: extracting image coordinates of a contour of the antenna from the segmented image; mapping the image coordinates to a pixel coordinate system, and transforming into binarization coordinates through Bohr operation, convoluting with mask coordinates set to generate a new mask; and filling up the new mask by using a color generator.

Further, the mapping the image coordinates to a pixel coordinate system includes transforming the coordinates system.

Preferably, an operation formula for generating the new mask is as below:

I(i, j)=5*I(i, j)−[I(i−1, j)+I(i+1, j)+I(i, j−1)+I(i, j+1)]; wherein I(i, j) represents an image center element.

Further, the mathematically linear modeling and fitting include implementing optimization of a data sample by using a gradient descent least square method.

Preferably, a model for fitting the straight line is f(x)=wTx+b; wherein wT represents a transpose of a weight matrix, and b represents an offset; and a formula for calculating the antenna downtilt is ⊖=arc tan(|k|); wherein k represents the slope of the straight line fitted by the gradient descent least square method.

Beneficial effects of embodiments of the present disclosure are as below: The embodiments of the present disclosure adopt a method for measuring an antenna downtilt based on linear regression fitting. An angle of the antenna downtilt is directly outputted and obtained after being processed by a deep learning network. Meanwhile, a segmented image obtained through mask instance segmentation allows a straight line obtained by mathematically linear modeling to be more fit to a true value of the antenna, ensuring the angle of the antenna downtilt to be more accurate. The method provided by the embodiments of the present disclosure avoids the danger of climbing measurement and reduces costs of installation sensors, and can more efficiently, safely and accurately obtain data of an antenna downtilt at low cost.

### BRIEF DESCRIPTION OF THE DRAWINGS

The present disclosure is further described below with reference to the accompanying drawings and examples.

FIG. 1 is a structural diagram of a deep learning method for image instance segmentation according to an embodiment of the present disclosure;

FIG. 2 is a flow block diagram of image instance segmentation according to an embodiment of the present disclosure;

FIG. 3 is a schematic diagram of aligning a network of interest by using a residual network according to an embodiment of the present disclosure;

FIG. 4 is a schematic diagram showing a corresponding relationship between an image coordinate system and a pixel coordinate system according to an embodiment of the present disclosure;

FIG. 5 is an arithograph of mask operation according to an embodiment of the present disclosure; and

FIG. 6 is a coordinate graph of mathematically linear modeling and fitting according to an embodiment of the present disclosure.

### DETAILED DESCRIPTION

An embodiment of the present disclosure discloses a method for measuring an antenna downtilt based on linear regression fitting, including: performing image instance segmentation on an inputted original antenna image using a deep learning method to obtain a segmented image; performing mask processing on the segmented image; performing mathematically linear modeling and fitting on the segmented image subjected to mask processing; and the performing mathematically linear modeling and fitting on the segmented image subjected to mask processing including: extracting pixel value coordinates of an antenna edge contour from the segmented image subjected to mask processing, and capturing a pixel value of a right-end edge on an antenna plane located in a front side; and fitting the pixel value coordinates into a straight line by using a mathematically linear modeling and fitting method and obtaining a slope of the straight line to obtain an angle of the antenna downtilt.

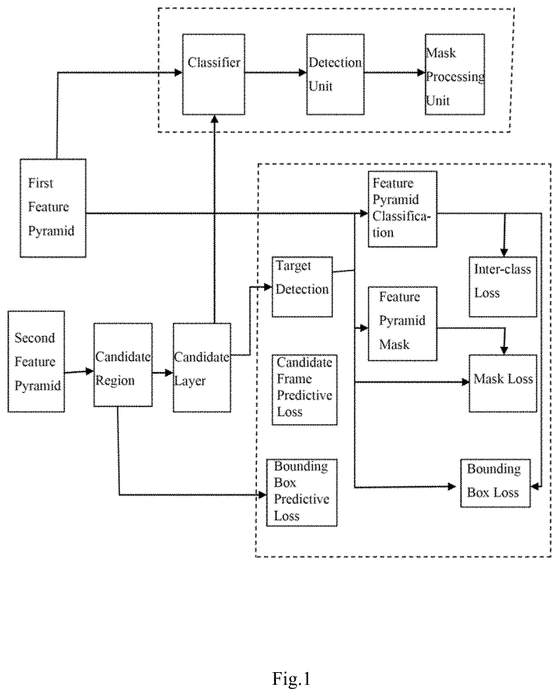

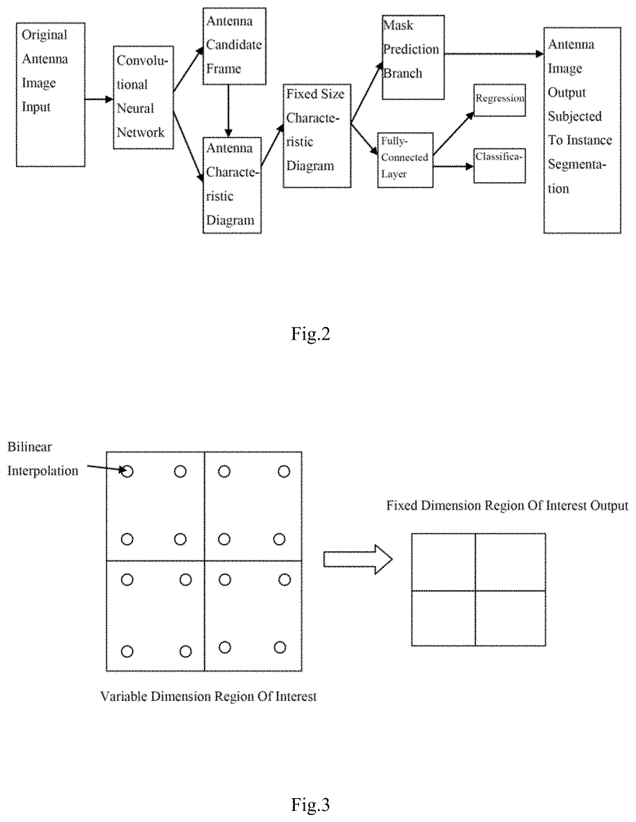

Referring to FIG. 1 and FIG. 2, in an embodiment, the performing image instance segmentation on an inputted antenna image using a deep learning method to obtain a segmented image includes: obtaining an antenna candidate box and an antenna characteristic diagram by using a convolutional neural network; and generating a region of interest from the antenna candidate box and obtaining a characteristic diagram of the region of interest with reference to the antenna characteristic diagram to perform pixel correction on the region of interest.

Further, the performing image instance segmentation on an inputted antenna image using a deep learning method to obtain a segmented image further includes: predicting the region of interest to obtain a regression bounding box mapped by the antenna characteristic diagram, and predicting a class of a pixel in the region of interest to obtain the segmented image.

Referring to FIG. 3, the pixel correction is performing alignment processing by using a residual network; and the pixel correction includes two quantization processes, which are a process of mapping from the region of interest to the antenna characteristic diagram and a process of mapping from the antenna characteristic diagram to the original antenna image respectively, ensuring one-to-one correspondence between input and output at the pixel level.

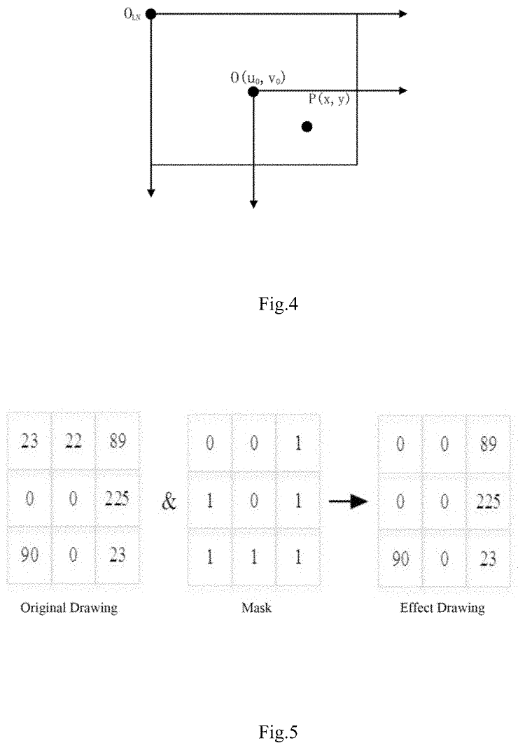

Referring to FIG. 5, in an embodiment, the performing mask processing on the segmented image include: extracting image coordinates of a contour of the antenna from the segmented image; mapping the image coordinates to a pixel coordinates system, and transforming into binarization coordinates through Bohr operation, convoluting with mask coordinates set to generate a new mask; and filling up the new mask by using a color generator.

Preferably, an operation formula for generating the new mask is as below:

I(i, j)=5*I(i, j)−[I(i−1, j)+I(i+1, j)+I(i, j−1)+I(i, j+1)]; wherein I(i, j) represents an image center element.

Referring to FIG. 4, in an embodiment, the mapping the image coordinates to a pixel coordinates system includes transforming the coordinates system. The pixel coordinates system and the image coordinates system are both on an imaging plane of the antenna image, but their origins and measurement units are different. The origin of the image coordinate system is an intersection point of an optical axis of a camera and the imaging plane, which is a center point of the imaging plane generally. The unit of the image coordinate system is mm, and the unit of the pixel coordinate system is pixel. The transformation between the image coordinate system and the pixel coordinate system is as follows: wherein dx and dy represent how many “mm”s each column and each row respectively represent, that is, 1 pixel=dx mm. The coordinate transformation formula is as follows:

$$\{ \begin{matrix}u = \frac{x}{d x} + {u}_{0} \\ v = \frac{y}{d y} + {v}_{0}\end{matrix} ⇒ [ \begin{matrix}u \\ v \\ 1\end{matrix} ] = [ \begin{matrix}\frac{\text{?}}{d x} & 0 & {u}_{0} \\ 0 & \frac{1}{d y} & {v}_{0} \\ 0 & 0 & 1\end{matrix} ] [ \begin{matrix}x \\ y \\ 1\end{matrix} ] \\ z \text{?} [ \begin{matrix}u \\ v \\ 1\end{matrix} ] = [ \begin{matrix}\frac{1}{d x} & 0 & {u}_{0} \\ 0 & \frac{1}{d y} & {v}_{0} \\ 0 & 0 & 1\end{matrix} ] [ \begin{matrix}f & 0 & 0 & 0 \\ 0 & f & 0 & 0 \\ 0 & 0 & 1 & 0\end{matrix} ] [ \begin{matrix}R & T \\ r & \\ 0 & \text{?}\end{matrix} ] [ \begin{matrix}{X}_{W} \\ {Y}_{W} \\ {Z}_{W} \\ 1\end{matrix} ] = [ \begin{matrix}{f}_{x} & 0 & {u}_{0} & 0 \\ 0 & {f}_{y} & {v}_{0} & 0 \\ 0 & 0 & 1 & 0\end{matrix} ] [ \begin{matrix}R & T \\ r & \\ 0 & 1\end{matrix} ] [ \begin{matrix}{X}_{W} \\ {Y}_{W} \\ {Z}_{W} \\ 1\end{matrix} ] ; \\ \text{?} \text{indicates text missing or illegible when filed}$$

wherein u0 and v0 respectively represent an abscissa and an ordinate of the center point of the image coordinate system; R represents a 3×3 orthogonal present matrix; and T represents a three-dimensional translation vector.

The segmented image needs to be masked by a mask branch network. As a convolutional network, the mask branch network takes a positive region selected by a region of interest classifier as input and generates a mask of the positive region. The generated mask corresponds to a low resolution of 28×28 pixels. As a soft mask represented by a floating point number, the generated mask has more details than a binary mask. The small size attribute of the mask contributes to keeping the light weight of the masked branch network. During the inference process, the predicted mask is enlarged to the size of a bounding box of the region of interest to provide final mask results.

Referring to FIG. 6, the mathematically linear modeling and fitting includes implementing optimization of a data sample by using a gradient descent least square method. Preferably, a model for fitting the straight line is f(x)=wTx+b; wherein wT represents a transpose of a weight matrix, and b represents an offset; and a formula for calculating the antenna downtilt is ⊖=arc tan(|k|); wherein k represents the slope of the straight line fitted by the gradient descent least square method.

In one embodiment, the calculation process is as follows: yi represents a true value of the ith point; f(xi) represents a predicted value obtained after being processed by a model function f; and an expression of Euclidean distance is obtained as below: distance=(yi−f(xi))2. From the perspective of a loss function, this formula is a square error, i.e., J(⊖)=½(Y−⊖X)2;

and a fitted objective function is obtained as:

$$arg {min}_{\vert ( w , b ) \text{?}} {\sum }^{m} \frac{1}{2} {( Y - θ X )}^{2} ;$$

$$\text{?} \text{indicates text missing or illegible when filed}$$

J(⊖) is calculated through a vector operation:

$$J ( θ ) = arg min \text{?} \text{?} \text{?} \sum \frac{1}{2} {( Y - θ X )}^{2} = \frac{1}{2} ( Y - θ X ) ( Y - θ X ) = \frac{1}{2} ( {θ}^{T} {X}^{T} X θ - {θ}^{T} {X}^{T} Y - {Y}^{T} X θ - {Y}^{T} Y ) ;$$

$$\text{?} \text{indicates text missing or illegible when filed}$$

A partial derivative calculation is performed on ⊖:

$$\frac{\partial J ( θ )}{\partial θ} = \frac{1}{2} ( 2 {X}^{T} X θ - 2 {X}^{T} Y ) = ( {X}^{T} X θ - {X}^{T} Y ) ;$$

By making the partial derivative be equal to zero and fitting the sample points onto an approximate straight line, the slope of the straight line may be obtained by least square error, and then the downtilt of an antenna of a base station is accurately obtained. As can be seen from the following arc tangent formula: ⊖=arc tan(|k|), wherein ⊖ represents the antenna downtilt, and k represents the slope of the straight line fitted by the gradient descent least square method.

The above descriptions are merely preferred embodiments of the present disclosure, but the present disclosure is not limited to the above embodiments. Any embodiment should fall within the protection scope of the present disclosure as long as it achieves the technical effects of the present disclosure by the same means.

We claim:

1. A method for measuring an antenna downtilt based on linear regression fitting, comprising:
performing image instance segmentation on an inputted original antenna image using a deep learning method to obtain a segmented image;
performing mask processing on the segmented image;
performing mathematically linear modeling and fitting on the segmented image subjected to mask processing; and
the performing mathematically linear modeling and fitting on the segmented image subjected to mask processing comprising: extracting pixel value coordinates of an antenna edge contour from the segmented image subjected to mask processing, and capturing a pixel value of a right-end edge on an antenna plane located in a front side; and fitting the pixel value coordinates into a straight line by using a mathematically linear modeling and fitting method and obtaining a slope of the straight line to obtain an angle of the antenna downtilt.

2. The method for measuring an antenna downtilt based on linear regression fitting according to claim 1, wherein the performing image instance segmentation on an inputted antenna image using a deep learning method to obtain a segmented image comprises:
obtaining an antenna candidate box and an antenna characteristic diagram by using a convolutional neural network; and
generating a region of interest from the antenna candidate box and obtaining a characteristic diagram of the region of interest with reference to the antenna characteristic diagram to perform pixel correction on the region of interest.

3. The method for measuring an antenna downtilt based on linear regression fitting according to claim 2, wherein the performing image instance segmentation on an inputted antenna image using a deep learning method to obtain a segmented image further comprises: predicting the region of interest to obtain a regression bounding box mapped from the antenna characteristic diagram, and predicting a class of a pixel in the region of interest to obtain the segmented image.

4. The method for measuring an antenna downtilt based on linear regression fitting according to claim 2, wherein the pixel correction is performing alignment processing by using a residual network; and the pixel correction comprises two quantization processes, which are mapping from the region of interest to the antenna characteristic diagram and mapping from the antenna characteristic diagram to the original antenna image respectively.

5. The method for measuring an antenna downtilt based on linear regression fitting according to claim 1, wherein the performing mask processing on the segmented image comprises: extracting image coordinates of a contour of the antenna from the segmented image; mapping the image coordinates to a pixel coordinate system, and transforming the into binarization coordinates through Bohr operation, convoluting with mask coordinate set to generate a new mask; and filling up the new mask by using a color generator.

6. The method for measuring an antenna downtilt based on linear regression fitting according to claim 5, wherein the mapping the image coordinates to a pixel coordinate system comprises transforming the coordinate system.

7. The method for measuring an antenna downtilt based on linear regression fitting according to claim 5, wherein generating the new mask is performed according to an operation formula:
I(i, j)=5*I(i, j)−[I(i−1, j)+I(i+1, j)+I(i, j−1)+I(i, j+1)]; wherein I(i, j) represents an image center element.

8. The method for measuring an antenna downtilt based on linear regression fitting according to claim 1, wherein the mathematically linear modeling and fitting comprise implementing optimization of a data sample by using a gradient descent least square method.

9. The method for measuring an antenna downtilt based on linear regression fitting according to claim 8, wherein the straight line is fit according to a model: f(x)=w^{T}x+b; wherein w^{T} represents a transpose of a weight matrix, and b represents an offset; and a formula for calculating the antenna downtilt is:
⊖=arc tan(|k|); wherein k represents the slope of the straight line fitted by the gradient descent least square method.

10. The method for measuring an antenna downtilt based on linear regression fitting according to claim 3, wherein the pixel correction is performing alignment processing by using a residual network; and the pixel correction comprises two quantization processes, which are mapping from the region of interest to the antenna characteristic diagram and mapping from the antenna characteristic diagram to the original antenna image respectively.
